(19) United States
(12) Patent Application Publication
(10) Pub. No.: US 2026/0033183 A1
(43) Pub. Date: Jan. 29, 2026

(54) DISPLAY DEVICE, ELECTRONIC DEVICE, AND METHOD FOR MANUFACTURING THE DISPLAY DEVICE

(71) Applicant: Samsung Display Co., Ltd., Yongin-Si (KR)

(72) Inventors: JUNYOUNG LEE, Yongin-si (KR); YOUN-WOONG KANG, Yongin-si (KR); SI JOON SONG, Yongin-si (KR); DONGHYUN LEE, Yongin-si (KR); JAEHAK LEE, Yongin-si (KR)

(21) Appl. No.: 19/198,433

(22) Filed: May 5, 2025

(30) Foreign Application Priority Data
Jul. 25, 2024 (KR) 10-2024-0098590

(51) Int. Cl. H10K 59/131; H10K 59/12; H10K 59/124; H10K 59/95

(52) U.S. Cl. CPC H10K 59/131; H10K 59/1201; H10K 59/124; H10K 59/95

(57) ABSTRACT

An electronic device includes a display panel including light emitting elements disposed on a front surface of the base layer, signal lines disposed on the front surface of the base layer and respectively connected to the light emitting elements, and pad electrodes extending in a first direction, arranged in a second direction, and respectively connected to the signal lines, wherein the base layer has an opening above the pad electrodes, a circuit board disposed on a rear surface of the base layer and including a film and a plurality of bump electrodes disposed on a surface of the film that is closest to the rear surface of the base layer. Metal patterns are disposed within the respective opening and contact the pad electrodes and the bump electrodes, and insulating patterns spaced apart from each other and being in contact with the metal patterns, respectively.

### CROSS-REFERENCE TO RELATED APPLICATION(S)

This U.S. non-provisional patent application claims priority under 35 U.S.C. § 119 of Korean Patent Application No. 10-2024-0098590 filed on Jul. 25, 2024, the entire content of which is hereby incorporated by reference.

### BACKGROUND

The present disclosure relates to a display device, an electronic device, and a method for manufacturing the display device, and more particularly, to a display device having improved reliability, an electronic device, and a method for manufacturing the display device.

Electronic devices such as smartphones, tablets, notebook computers, navigation systems for vehicles, and smart televisions are being developed. Each of the electronic equipment may include a display device for providing information.

Various types of display devices are being developed to satisfy user's UX/UI. Display devices are being developed to provide a wide display area and a narrow non-display area.

### SUMMARY

The present disclosure provides a display device having a reduced non-display area, an electronic device, and a method for manufacturing the display device.

An embodiment of the inventive concept provides an electronic device including: a base layer; a display panel including a plurality of light emitting elements disposed on a front surface of the base layer, a plurality of signal lines disposed on the front surface of the base layer and respectively connected to the light emitting elements, and a plurality of pad electrodes extending in a first direction, arranged in a second direction intersecting the first direction, and respectively connected to the signal lines, wherein the base layer has an opening above the pad electrodes a circuit board disposed on a rear surface of the base layer and including a film and a plurality of bump electrodes disposed on a surface of the film that is closest to the rear surface of the base layer, the bump electrodes extending in the first direction, and arranged in the second direction; a plurality of metal patterns disposed within the respective opening and contacting one of the pad electrodes and one of the bump electrodes; and a plurality of insulating patterns spaced apart from each other and being in contact with the metal patterns, respectively, wherein each of the bump electrodes extends beyond a side edge of the film, and the insulating patterns are disposed between the side edge of the film and the metal patterns, respectively.

In an embodiment, each of the metal patterns may include: a first portion overlapping at least a portion of one of the plurality of bump electrodes; and a second portion covering a side surface of the one of the plurality of bump electrodes.

In an embodiment, the second portion may be electrically connected to the pad electrodes.

In an embodiment, the insulating patterns may overlap the plurality of bump electrodes on the plane and be in contact with side surfaces of the metal patterns.

In an embodiment, the insulating patterns may be spaced apart from the film.

In an embodiment, a surface of each of the insulating patterns is flush with a surface of each of the metal patterns, respectively.

In an embodiment, each of the insulating patterns may include at least one of polyacrylic acid, polymethyl methacrylate, polyacrylamide, or polybutylacrylate.

In an embodiment, the display device may further include a driving chip mounted on the circuit board, wherein the bump electrodes may be connected to the driving chip.

In an embodiment, the base layer may include a first synthetic resin layer, a second synthetic resin layer, and inorganic layers disposed between the first synthetic resin layer and the second synthetic resin layer, wherein the opening is defined in the first synthetic resin layer, and the pad electrodes may be connected to conductive patterns disposed on the base layer through a contact hole passing through the base layer.

In an embodiment, the display device may further include an adhesive layer disposed between the pad electrodes and the bump electrodes, wherein the adhesive layer may include a non-conductive film.

In an embodiment of the inventive concept, a method of manufacturing a display device includes: forming an opening in a base layer to expose a plurality of pad electrodes; providing a circuit board comprising a film and a plurality of bump electrodes disposed on the film, and positioning the film such that the plurality of bump electrodes overlap the plurality of pad electrodes, respectively; forming a resin layer on the plurality of bump electrodes; forming a metal layer on the plurality of bump electrodes; and patterning the resin layer and the metal layer to form a plurality of insulating patterns spaced apart from each other and a plurality of metal patterns spaced apart from each other, wherein the plurality of pad electrodes and the plurality of bump electrodes are electrically connected by the plurality of metal patterns.

In an embodiment, the patterning of the resin layer and the metal layer includes using a laser.

In an embodiment, the forming of the metal layer includes providing the metal layer in a liquid form.

In an embodiment, the forming of the resin layer may further include hardening a preliminary resin layer to form the resin layer by irradiating with ultraviolet (UV) rays.

In an embodiment, an entire surface of the preliminary resin layer may be irradiated with the ultraviolet (UV) rays.

In an embodiment, The method may further include, after the patterning of the preliminary resin layer to form the insulating patterns, hardening the insulating patterns.

In an embodiment, the hardening of the preliminary resin layer may include irradiating with intense pulsed light (IPL).

In an embodiment, the method may further include, after the patterning of the metal layer to form the metal patterns, hardening the metal patterns at the same time as hardening of the insulating patterns.

In an embodiment of the inventive concept, an apparatus for manufacturing a display device includes: a first nozzle part configured to supply a resin; a hardening part connected to the first nozzle part and configured to irradiate ultraviolet (UV) rays onto the resin; a connection jig connected to the hardening part; and a second nozzle part disposed diagonally relative to the first nozzle part by the connection jig and configured to supply ink.

In an embodiment, the ink may include at least one of silver (Ag), copper (Cu), or aluminum (Al).

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic device according to an embodiment of the inventive concept;

FIG. 2 is an exploded perspective view of the electronic apparatus according to an embodiment of the inventive concept;

FIG. 3 is a cross-sectional view of a display device, which is taken along line I-I′ of FIG. 2;

FIG. 4 is a schematic cross-sectional view of a display module according to an embodiment of the inventive concept;

FIG. 5 is a plan view of the display panel according to an embodiment of the inventive concept;

FIG. 6 is a cross-sectional view of a display module according to an embodiment of the inventive concept;

FIG. 7 is a plan view illustrating a rear surface of the display panel according to an embodiment of the inventive concept;

FIG. 8 is a partially enlarged plan view of the display device according to an embodiment of the inventive concept;

FIG. 9A is a cross-sectional view of the display device, which is taken along line II-II′ of FIG. 8;

FIG. 9B is an enlarged view of an area AA′ of FIG. 9A;

FIG. 10 is a perspective view illustrating an apparatus for manufacturing a display device according to an embodiment of the inventive concept;

FIGS. 11A to 11G are views illustrating a method for manufacturing a display device according to an embodiment of the inventive concept;

FIGS. 12A and 12B are views illustrating the method for manufacturing a display device according to an embodiment of the inventive concept; and

FIGS. 13A and 13B are views illustrating the method for manufacturing a display device according to an embodiment of the inventive concept.

### DETAILED DESCRIPTION

In this specification, it will also be understood that when one component (or region, layer, portion) is referred to as being “on,” “connected to,” or “coupled to” another component, it can be directly disposed/connected/coupled on/to the one component, or an intervening third component may be present.

Like reference numerals refer to like elements throughout. Also, in the figures, the thickness, ratio, and dimensions of components are exaggerated for clarity of illustration. The term “and/or” includes any and all combinations of one or more of the associated components.

It will be understood that although the terms such as “first” and “second” are used herein to describe various elements, these elements should not be limited to a certain order or priority by these terms. The terms are only used to distinguish one component from other components. For example, a first element referred to as a first element in an embodiment can be referred to as a second element in another embodiment without departing from the scope of the appended claims. The terms of a singular form may include plural forms unless referred to the contrary.

Also, “under,” “below,” “above,” “upper,” and the like are used for explaining relative positions of components illustrated in the drawings. The terms may be referring to directions in the drawings.

The meaning of “include” or ‘comprise’ specifies a property, a fixed number, a process, an operation, an element, a component or a combination thereof, but does not exclude other properties, fixed numbers, processes, operations, elements, components or combinations thereof.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, exemplary embodiments of the inventive concept will be described with reference to the accompanying drawings.

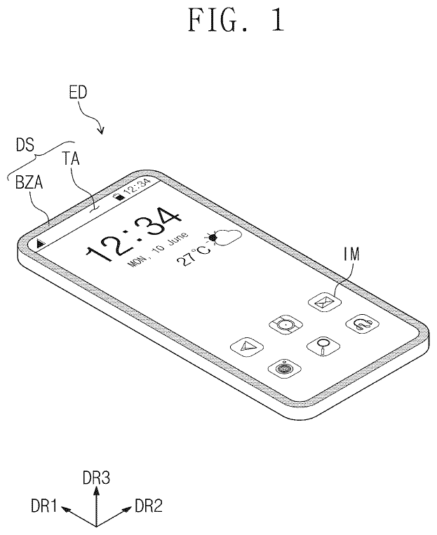

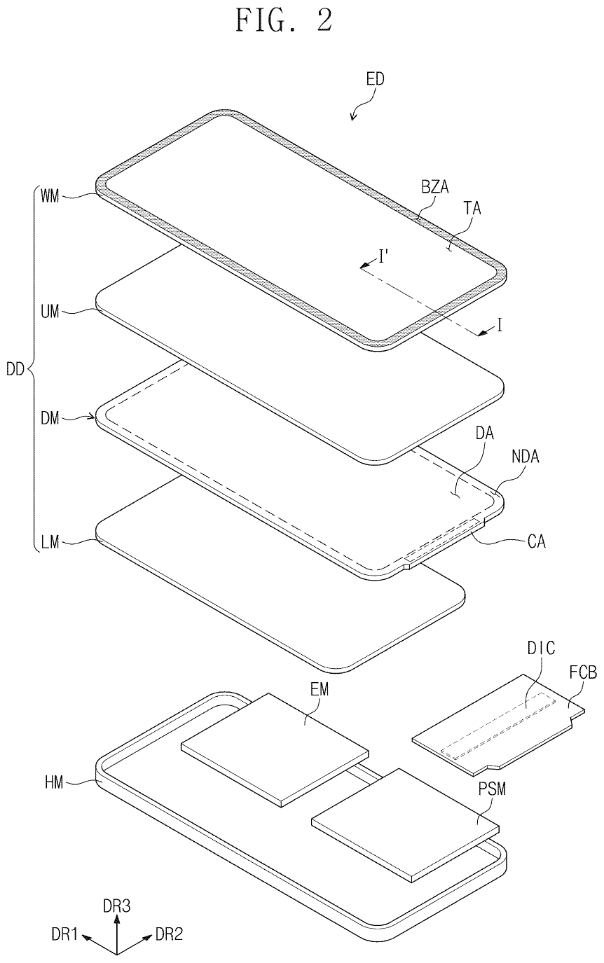

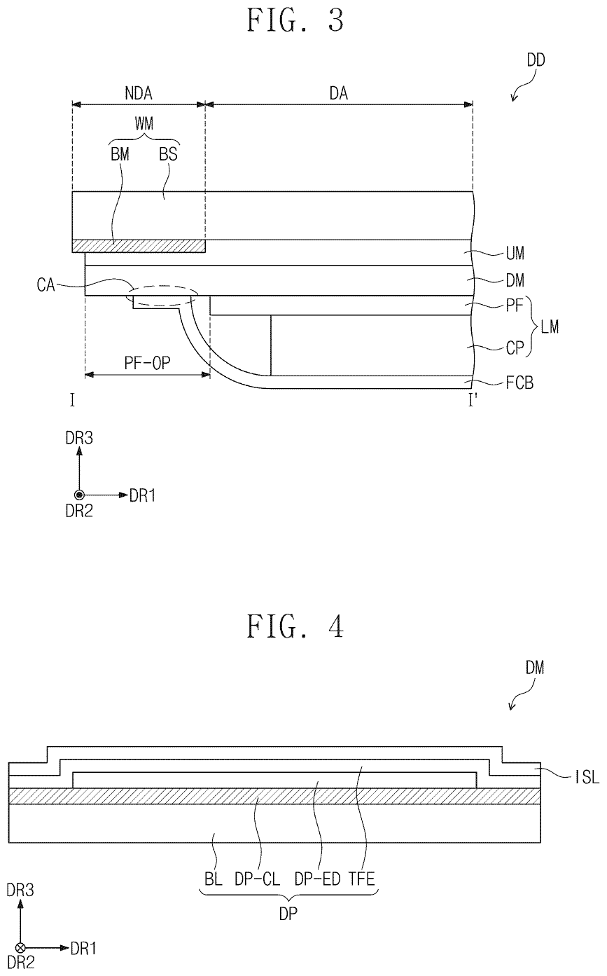

FIG. 1 is a perspective view of an electronic device according to an embodiment of the inventive concept. FIG. 2 is an exploded perspective view of the electronic apparatus according to an embodiment of the inventive concept. FIG. 3 is a cross-sectional view of a display device, which is taken along line I-I′ of FIG. 2;

Referring to FIG. 1, an electronic device ED according to an embodiment of the inventive concept may include a display surface DS defined by a first direction DR1 and a second direction DR2 intersecting the first direction DR1. The electronic device ED may provide an image IM to a user through the display surface DS.

Hereinafter, a direction substantially perpendicular to a plane defined by the first direction DR1 and the second direction DR2 may be defined as a third direction DR3. The third direction DR3 may be used as a reference direction in which front and rear surfaces of each member are distinguished from each other. As used herein, “on the plane” may be defined as a state in which the electronic device ED is viewed in the third direction DR3.

In an embodiment of the inventive concept, the electronic device ED may be a foldable electronic device that is foldable about a folding axis. The folding axis may be parallel to the first direction DR1 or the second direction DR2, and a folding area may be defined on a portion of the display area. The electronic device ED may be in-folded so that the display areas face each other or may be out-folded so that the display areas are away from each other.

Referring to FIG. 2, the electronic device ED may include a display device DD, an electronic module EM, a power module PSM, and a housing HM. FIG. 2 schematically illustrates the electronic device ED, which may further include a mechanical structure (e.g., a hinge) for controlling an operation (e.g., folding or rolling) of the display device EM.

The display device EM may generate an image and detect an external input. The display device EM may include a window WM, an upper member UM, a display module DM, a lower member LM, a circuit board (or flexible circuit board) FCB, and a driving chip DIC. The upper member UM may include members disposed above the display module DM, and the lower member LM may include members disposed below the display module DM.

The window WM may include an optically transparent insulation material. For example, the window WM may include glass or plastic. A front surface of the window WM may define the display surface DS of the display device EM where images are displayed. The display surface DS may include a transmission area TA and a bezel area BZA. The transmission area TA may be an optically transparent area. For example, the transmission area TA may be an area having visible light transmittance of about 90% or more.

The bezel area BZA may be an area having relatively low light transmittance compared to that of the transmission area TA. The bezel area BZA may define a shape of the transmission area TA. The bezel area BZA may be adjacent to the transmission area TA and may surround the transmission area TA. However, this embodiment is only an example, and the shapes of the bezel area BZA and the transmission area TA may be modified.

The display module DM may include a display area DA and a non-display area NDA. The display area DA may be an area that is activated according to an electrical signal. The non-display area NDA may be adjacent to the display area DA. The non-display area NDA may surround the display area DA. The non-display area NDA may be an area covered by the bezel area BZA and may not be visible from the outside.

The display module DM may have a substantially rectangular shape. Here, “substantially rectangular shape” may include not only a rectangular shape in the mathematical sense, but also a shape similar to a rectangle that may be recognized as a rectangle by a user. For example, the substantially rectangular shape may include a rectangular shape having rounded corner area. In addition, the substantially rectangular shape is not necessarily limited to a shape having a straight edge or a sharp corner of the display panel, and may include a curved area.

A contact area CA may be disposed at one side of the non-display area NDA. The contact area CA may be an area electrically bonded (or connected) to a circuit board FCB described later. In this embodiment, the contact area CA may be defined by the rear surface of the display module DM.

The upper member UM may include a protective film or an optical film. The optical film may include a polarizer and a retarder to reduce reflection of external light. The lower member LM may include a protective film that protects the display panel DP, a support member that supports the display panel, a digitizer, etc. Detailed descriptions of the upper member UM and lower member LM will be provided below.

The circuit board FCB may be disposed at a lower side of the display module DM. The circuit board FCB may be bonded to the rear surface of the display panel. The circuit board FCB may electrically connect the display panel to the main circuit board. The circuit board FCB may include at least one insulating layer and at least one conductive layer. The conductive layer may include a plurality of signal lines.

The driving chip DIC may be mounted on the circuit board FCB. The driving chip DIC may include a driving circuit for driving pixels of the display panel, for example, a data driving circuit. FIG. 2 illustrates a structure in which a driving chip DIC is mounted on the circuit board FCB, but the inventive concept is not limited thereto. For example, the driving chip DIC may be mounted on the display module DM or the main circuit board.

The electronic module EM may include a control module, a wireless communication module, an image input module, an audio input module, an audio output module, a memory, and an external interface module. The electronic module EM may include a main circuit board, and the modules may be mounted on the main circuit board or electrically connected to the main circuit board through a flexible circuit board. The electronic module EM may be electrically connected to the power module PSM.

Although not shown separately, the electronic device ED may further include an electro-optical module. The electro-optical module may be an electronic component that outputs or receives an optical signal. The electro-optical module may include a camera module and/or a proximity sensor. The camera module may photograph an external image through a portion of the display panel DP.

The housing HM illustrated in FIG. 2 may be coupled to the display device EM, particularly the window WM, to accommodate other modules. The housing HM is illustrated as having an integrated shape, but is not limited thereto. The housing HM may include a plurality of portions (e.g., side edge portions and bottom portions) that are coupled to each other.

Referring to FIG. 3, the window WM may include a base substrate BS and a bezel pattern BM disposed on a bottom surface of the base substrate BS. The base substrate BS may include a synthetic resin film or a glass substrate. The base substrate BS may have a multilayer structure. The base substrate BS may include a thin film glass substrate, a protective film disposed on the thin film glass substrate, and an adhesive layer that bonds the thin film glass substrate to the protective film.

The bezel pattern BM may be provided as a colored light blocking film, for example, in a coating manner.

The bezel pattern BM may include a base material and a dye or pigment mixed with the base material. The bezel pattern BM may overlap the non-display area NDA and the bezel area BZA, which are illustrated in FIG. 2. In this specification, “areas/portions A correspond to areas/portions B” means the two area/portions overlap each other and do not necessarily have the same surface area. The bezel pattern BM may be disposed on a bottom surface of the base substrate BS. When the base substrate BS has a multilayer structure, the bezel pattern BM may be disposed between interfaces defined by the plurality of layers. For example, the bezel pattern BM may be disposed between the thin film glass substrate and the protective film. Although not shown separately, the window WM may further include at least one of a hard coating layer, an anti-fingerprint layer, or an anti-reflection layer on a top surface of the base substrate BS.

The upper member UM may include an upper film. The upper film may include a synthetic resin film. The synthetic resin film may include polyimide, polycarbonate, polyamide, triacetylcellulose, polymethylmethacrylate, or polyethylene terephthalate.

The upper film may absorb an external impact applied to the front surface of the display device EM. In an embodiment of the inventive concept, the display module DM may include a color filter replacing a polarizing film as an anti-reflection member. This may result in a reduction in front impact strength of the display device EM. The upper film may compensate for the reduced impact strength by applying the color filter.

The upper member UM may overlap the bezel area BZA and the transmission area TA. The upper member UM may overlap only a portion of the bezel area BZA. A portion of the bezel pattern BM may be exposed from the upper member UM. In an embodiment of the inventive concept, the upper member UM may be omitted. In an embodiment of the inventive concept, the upper member UM may be replaced with the optical film including the polarizer and the retarder.

Although not shown, an adhesive layer through which the upper member UM and the window WM are bonded to each other may be further provided between the upper member UM and the window WM. The adhesive layer may be a pressure-sensitive adhesive film or an optically transparent adhesive member.

The display module DM may be disposed below the upper member UM. The display module DM may overlap the bezel area BZA and the transmission area TA. The display module DM may completely overlap the upper member UM within the bezel area BZA. A side surface of the display module DM may be aligned with a side surface of the upper member UM, and an edge of the display module DM on a plane may be aligned with an edge of the upper member UM. However, this embodiment is only an example, and an edge of the upper member UM and an edge of the display module DM may be misaligned within the bezel area BZA, and are not limited to any one embodiment.

A contact area CA may be defined on the non-display area NDA. The contact area CA may be an area on which the circuit board FCB and the display module DM are connected.

The contact area CA of the display module DM within the bezel area BZA may overlap the upper member UM. A portion of the display module DM corresponding to the contact area CA may be coupled to the bottom surface of the upper member UM by the adhesive layer. The contact area CA may overlap the upper member UM, and a portion of the contact area CA of the display module DM may be coupled to the upper member UM so that, when the circuit board FCB is bonded to the contact area CA, the upper member UM may sufficiently support the contact area CA.

The lower member LM may include a lower film PF and a cover panel CP. In an embodiment of the inventive concept, the lower member LM may further include a support plate and a digitizer.

The lower film PF may expose the contact area CA of the display module DM. The lower film PF may have a size less than that of the display module DM. For example, the lower film PF may overlap only the display area DA of the display module DM. In the lower film PF, an open area PF-OP corresponding to the non-display area NDA may be defined. The contact area CA of the display module DM may be exposed by the open area PF-OP of the lower film PF. Within the open area PF-OP, a partial area of the display module DM may be connected to the circuit board FCB. Alternatively, the lower film PF may have a size substantially corresponding to the display module DM. In this case, the open area PF-OP passing through the lower film PF may be defined, and the contact area CA may be exposed through the open area PF-OP.

A cover panel CP may be disposed below the lower film PF. The cover panel CP may increase in resistance to compressive force caused by external pressing. Therefore, the cover panel CP may prevent deformation of the display module DM. The cover panel CP may include a flexible plastic material such as polyimide or polyethylene terephthalate. In addition, the cover panel CP may be a colored film having low light transmittance. The cover panel CP may absorb light incident from the outside. For example, the cover panel CP may be a black synthetic resin film. If the display device DD is viewed from the upper side of the window WM, components disposed below the cover panel CP may not be visible to the user.

Although not shown, a support plate may be further disposed below the cover panel CP. The support plate may include a high-strength metal material. Alternatively, the support plate may include a reinforced fiber composite.

The circuit board FCB may include an insulating film and conductive lines mounted on the insulating film. Electronic components may be electrically connected to the display module DM by being connected to signal lines. The electronic components may generate various electrical signals, for example, a signal for generating an image or a signal for detecting an external input. The electronic components may process the detected signal.

Referring to FIGS. 2 and 3, the circuit board FCB may be coupled (bonded to the rear surface) to the rear surface of the display panel. When bonded to the rear surface, the non-display area NDA of the display module DM may not be bent. Thus, defects occurring when the non-display area NDA of the display module DM is bent may be prevented or reduced. In addition, a surface area of the bezel area BZA of the window WM to cover the non-display area NDA of the display module DM may be reduced.

FIG. 4 is a schematic cross-sectional view of the display module according to an embodiment of the inventive concept.

Referring to FIG. 4, the display module DM may include a display panel DP and an input sensing layer ISL. The display panel DP may include a base layer BL, a circuit layer DP-CL, a display element layer DP-ED, and an encapsulation layer TFE.

The circuit layer DP-CL may be disposed on a top surface of the base layer BL. The base layer BL may be a flexible substrate capable of being bent, folded, rolled, etc. The base layer BL may be a glass substrate, a metal substrate, or a polymer substrate. However, an embodiment of the inventive concept is not limited thereto, and the base layer BL may be an inorganic layer, an organic layer, or a composite material layer.

The base layer BL may have a multilayer structure. For example, the base layer BL may include a first synthetic resin layer, a second synthetic resin layer, and inorganic layers disposed between the first synthetic resin layer and the second synthetic resin layer. Each of the first and second synthetic resin layers may include a polyimide-based resin.

The circuit layer DP-CL may be disposed on the base layer BL. The circuit layer DP-CL may include a plurality of insulating layers, a plurality of semiconductor patterns, a plurality of conductive patterns, and signal lines. The circuit layer DP-CL may include a driving circuit of the pixel.

The display element layer DP-ED may be disposed on the circuit layer DP-CL. The display element layer DP-ED may include a light emitting element. The light emitting element may include an organic light emitting material, an inorganic light emitting material, an organic-inorganic light emitting material, a quantum dot, a quantum rod, a micro LED, or a nano LED.

The encapsulation layer TFE may be disposed on the display element layer DP-ED. The encapsulation layer TFE may protect the display element layer DP-ED, i.e. the light emitting element, from foreign substances such as moisture, oxygen, and dust particles. The encapsulating layer TFE may include at least one encapsulating inorganic layer. The encapsulation layer TFE may include a laminated structure of a first encapsulating inorganic layer/encapsulating organic layer/second encapsulating inorganic layer.

The input sensing layer ISL may be directly disposed on the display panel DP. The input sensing layer ISL may sense a user's input, for example, using an electromagnetic induction manner or an electrostatic capacitance manner. The display panel DP and the input sensing layer ISL may be formed through a continuous process. Here, “directly disposed” may mean that a third component is not disposed between the input sensing layer ISL and the display panel DP. For example, a separate adhesive layer may not be disposed between the input sensing layer ISL and the display panel DP.

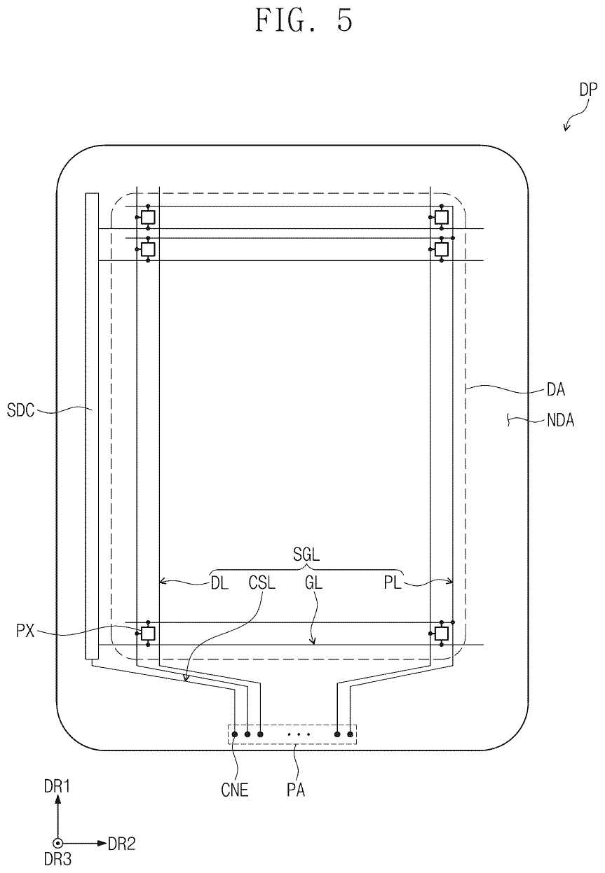

FIG. 5 is a plan view of the display panel according to an embodiment of the inventive concept.

Referring to FIG. 5, the display panel DP may include a scan driving circuit SDC, a plurality of signal lines SGL, and a plurality of pixels PX. The plurality of pixels PX may be disposed on the display area DA. Each pixel PX may include a light emitting element and a pixel driving circuit connected thereto. The scan driving circuit SDC, the plurality of signal lines SGL, and the pixel driving circuit may be included in the circuit layer DP-CL (see FIG. 4).

The scan driving circuit SDC may include a gate driving circuit. The gate driving circuit may generate a plurality of scan signals and sequentially output the plurality of scan signals to a plurality of scan lines GL described later. The scan driving circuit SDC may further include a light emitting driving circuit that is distinguished from the gate driving circuit. The light emitting driving circuit may output scan signals to another group of scan lines.

The scan driving circuit SDC may include a plurality of thin film transistors that are manufactured through the same process as the driving circuit of the pixel PX, e.g., a low temperature polycrystalline silicon (LTPS) process or a low temperature polycrystalline oxide (LTPO) process.

The plurality of signal lines SGL includes scan lines GL, data lines DL, a power line PL, and a control signal line CSL. Each of the scan lines GL may be connected to a corresponding pixel PX of the plurality of pixels PX, and each of the data lines DL may be connected to a corresponding pixel PX of the plurality of pixels PX. The power line PL may be connected to the plurality of pixels PX. The data lines DL may provide data signals to the pixels PX. The control signal line CSL may provide control signals to the scan driving circuit SDC.

The power lines PL may be provided in plurality. For example, the power line PL may include a first power line receiving a first power voltage and a second power line receiving a second power voltage having a level higher than that of the first power voltage. The first power voltage may be provided to the pixels PX through the first power line, and the second power voltage may be provided to the pixels PX through the second power line. In FIG. 5, one control signal line CSL is illustrated as an example, but this embodiment is not limited thereto, and a plurality of control signal lines CSL may be provided.

The scan lines GL, the data lines DL, and the power lines PL may overlap the display area DA and the non-display area NDA. The control signal line CSL may overlap the non-display area NDA. The plurality of signal lines SGL may be aligned at one side of the non-display area NDA at the end. Each of the plurality of signal lines SGL may have a single shape, but may include a plurality of portions disposed on different layers. Here, the different portions divided by the insulating layer may be connected through a contact hole passing through the insulating layer. For example, the data lines DL may include a first portion disposed on the display area DA, and a second portion disposed on the non-display area NDA and on a layer different from that on which the first portion is disposed. The first portion and the second portion may include different materials, respectively.

The pad area PA may correspond to the contact area CA illustrated in FIGS. 2 and 3. A plurality of connection electrodes CNE may be disposed on the pad area PA. The connection electrodes CNE may be provided at ends of the signal lines SGL, respectively. The connection electrodes CNE may be in contact with connection parts of the main circuit board, respectively. The plurality of signal lines SGL may be electrically connected to the main circuit board MCB (see FIG. 3) through the pad area PA.

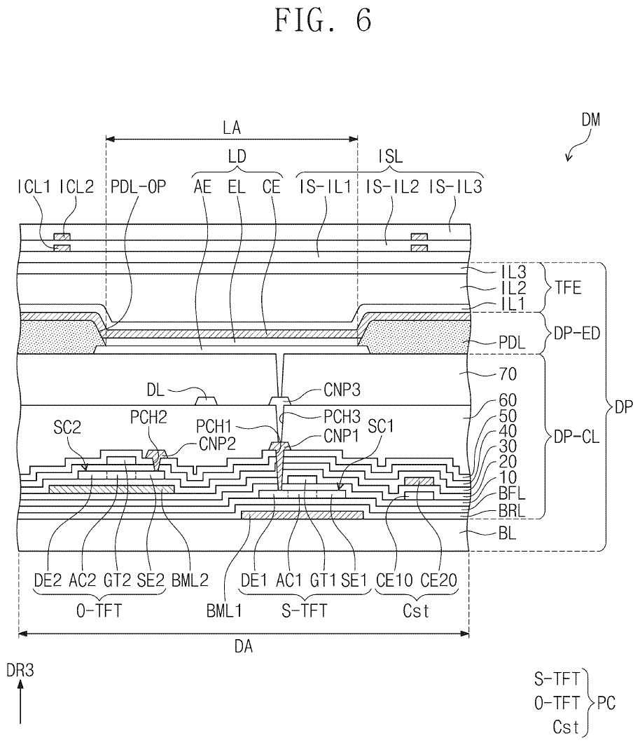

FIG. 6 is a cross-sectional view of the display module according to an embodiment of the inventive concept. FIG. 6 illustrates a cross-sectional view of the display module DM corresponding to the pixel PX of FIG. 5.

The pixel driving circuit PC that drives the light emitting element LD may include a plurality of pixel driving elements. The pixel driving circuit PC may include a plurality of transistors S-TFT and O-TFT and a capacitor Cst. The plurality of transistors S-TFT and O-TFT may include a silicon transistor S-TFT and an oxide transistor O-TFT. FIG. 6 illustrates the silicon transistor S-TFT and the oxide transistor O-TFT as examples, but this embodiment is not limited thereto. The pixel driving circuit PC may include only one type of transistor of the silicon transistor S-TFT and the oxide transistor O-TFT.

Referring to FIG. 6, the base layer BL may be illustrated as a single layer. The base layer BL may include a synthetic resin such as polyimide. The base layer BL may be provided by applying a synthetic resin layer on a work substrate (or carrier substrate). When the display module DM is completed by performing the following process, the work substrate may be removed.

A first shielding electrode (or shielding electrode) BML1 may be disposed on the base layer BL. The first shielding electrode BML1 may be disposed to correspond to the silicon transistor S-TFT. The first shield electrode BML1 may receive a bias voltage. The first shield electrode BML1 may also receive the first power supply voltage. The first shielding electrode BML1 may block an electric potential caused by polarization from affecting the silicon transistor S-TFT. The first shielding electrode BML1 may block external light from reaching the silicon transistor S-TFT. In an embodiment of the inventive concept, the first shielding electrode BML1 may be a floating electrode that is isolated from the other electrode or line. The first shielding electrode BML1 may include a metal, such as molybdenum.

A barrier layer BRL may be disposed on the base layer BL and the first shielding electrode BML1. The barrier layer BRL may include at least one inorganic layer. The barrier layer BRL may include a silicon oxide layer and a silicon nitride layer. Each of the silicon oxide layer and the silicon nitride layer may be provided in plurality, and the silicon oxide layers and silicon nitride layers may be alternately laminated. The barrier layer BRL may prevent foreign substances from being introduced from the outside.

The buffer layer BFL may be disposed on the base layer BRL. The buffer layer BFL may include at least one inorganic layer. The buffer layer BFL may include a silicon oxide layer and a silicon nitride layer. The buffer layer BFL may prevent metal atoms or impurities from being diffused from the base layer BL to the first semiconductor pattern SC1 disposed at the upper side.

The first semiconductor pattern SC1 may be disposed on the buffer layer BFL. The first semiconductor pattern SC1 may include a silicon semiconductor. For example, the silicon semiconductor may include amorphous silicon, polycrystalline silicon, etc. For example, the first semiconductor pattern SC1 may include low-temperature polysilicon.

The first semiconductor pattern SC1 may have different electrical properties depending on whether the first semiconductor pattern SC1 is doped. The first semiconductor pattern SC1 may include a first region having high conductivity and a second region having low conductivity. The first region may be doped with an N-type dopant or a P-type dopant. The P-type transistor may include a doped region doped with the P-type dopant, and the N-type transistor may include a doped region doped with the N-type dopant. The second region may be an undoped region or a region doped at a lower concentration than the first region. In this embodiment, the first semiconductor pattern SC1 may be an N-type transistor.

The conductivity of the first region may be greater than that of the second region, and the first region may substantially serve as an electrode or a signal line. The second region may substantially correspond to a channel region (or active region) of the transistor. That is to say, a portion of the first semiconductor pattern SC1 may be a channel of the transistor, another portion may be a source or drain of the transistor, and further another portion may be a connection electrode or a connection signal line.

A source region SE1, a channel region AC1 (or active region), and a drain region DE1 of the silicon transistor S-TFT may be provided from the first semiconductor pattern SC1. The source region SE1 and the drain region DE1 may extend in opposite directions from the channel region AC1 in a cross-section.

The first insulating layer 10 may be disposed on the buffer layer BFL. The first insulating layer 10 may be an inorganic layer. The first insulating layer 10 may be a single-layered silicon oxide layer. However, an embodiment is not limited thereto, and the first insulating layer 10 may have a multilayer structure.

The first gate (or first gate electrode) GT1 of the silicon transistor S-TFT may be disposed on the first insulating layer 10. The first gate GT1 may overlap the channel region AC1. The first gate GT1 may be a portion of a metal pattern. In the process of doping the first semiconductor pattern SC1, the first gate GT1 may be a mask. The first electrode CE10 of the storage capacitor Cst may be disposed on the first insulating layer 10. Unlike that illustrated in FIG. 6, the first electrode CE10 may have a shape integrated with the gate GT1.

The second insulating layer 20 may be disposed on the first insulating layer 10 and may cover the first gate GT1. In an embodiment of the inventive concept, an upper electrode overlapping the first gate GT1 may be further disposed on the second insulating layer 20. A second electrode CE20 overlapping the first electrode CE10 may be disposed on the second insulating layer 20. The upper electrode may have a shape integrated with the second electrode CE20 on the plane.

The second shielding electrode BML2 may be disposed on the second insulating layer 20. The second shielding electrode BML2 may be disposed to correspond to the oxide transistor O-TFT. In an embodiment of the inventive concept, the second shielding electrode BML2 may be omitted. According to an embodiment of the inventive concept, the first shielding electrode BML1 may extend to a lower portion of the oxide transistor O-TFT to replace the second shielding electrode BML2.

The third insulating layer 30 may be disposed on the second insulating layer 20. The second semiconductor pattern SC2 may be disposed on the third insulating layer 30. The second semiconductor pattern SC2 may include a channel region AC2 of an oxide transistor O-TFT. The second semiconductor pattern SC2 may include a metal oxide semiconductor. The second semiconductor pattern SC2 may include transparent conductive oxide TCO such as indium tin oxide (ITO), indium zinc oxide (IZO), indium gallium zinc oxide (IGZO), zinc oxide (ZnOx), or indium oxide (In₂O₃).

The metal oxide semiconductor may include a plurality of regions SE2, AC2, and DE2 distinguished depending on whether the transparent conductive oxide is reduced or not. The region in which the transparent conductive oxide is reduced (hereinafter, referred to as a reduced region) has greater conductivity than a region in which the transparent conductive oxide is not reduced (hereinafter, referred to as a non-reduced region). The reduction region may essentially act as a source/drain or signal line of the transistor. The non-reducing region may essentially correspond to a semiconductor region (or channel) of the transistor. In other words, a partial area of the second semiconductor pattern SC2 may be a semiconductor area of the transistor, another area may be a source area SE2/drain area DE2 of the transistor, and further another area may be a signal transmission area.

The fourth insulating layer 40 may be disposed on the third insulating layer 30. In an embodiment of the inventive concept, the fourth insulating layer 40 may overlap the second gate GT2 (hereinafter, referred to as the second gate) of the oxide transistor O-TFT.

The second gate GT2 may be disposed on the fourth insulating layer 40. The second gate GT2 may be a portion of the metal pattern. The second gate GT2 may overlap the channel region AC2.

The fifth insulating layer 50 may be disposed on the fourth insulating layer 40 and may cover the second gate GT2. Each of the first insulating layer 10 to the fifth insulating layer 50 may be an inorganic layer.

A conductive layer may be disposed on the fifth insulating layer 50. In an embodiment of the inventive concept, the conductive layer may include a first connection pattern CNP1 and a second connection pattern CNP2. Since the first connection pattern CNP1 and the second connection pattern CNP2 are formed through the same process, the first connection pattern CNP1 and the second connection pattern CNP2 may have the same material and the same laminated structure. The first connection pattern CNP1 may be connected to the drain region DE1 of the silicon transistor S-TFT through a first pixel contact hole PCH1 passing through the first to fifth insulating layers 10, 20, 30, 40, and 50. The second connection pattern CNP2 may be connected to the source region SE2 of the oxide transistor O-TFT through a second pixel contact hole PCH2 passing through the fourth and fifth insulating layers 40 and 50. The connection relationship between the first connection pattern CNP1 and the second connection pattern CNP2 for the silicon transistor S-TFT and the oxide transistor O-TFT is not necessarily limited thereto.

The sixth insulating layer 60 may be disposed on the fifth insulating layer 50. The third connection pattern CNP3 and the data line DL may be disposed on the sixth insulating layer 60. The third connection pattern CNP3 may be connected to the first connection pattern CNP1 through a third pixel contact hole PCH3 passing through the sixth insulating layer 60. The seventh insulating layer 70 may be disposed on the sixth insulating layer 60. The third connection pattern CNP3 and data line DL may be formed through the same process and thus may have the same material and the same laminated structure. Each of the sixth insulating layer 60 and the seventh insulating layer 70 may be an organic layer.

Each of the first shielding electrode BML1, the first gate GT1, the second electrode CE20, and the second gate GT2 may include molybdenum (Mo), an alloy containing molybdenum, titanium (Ti), or an alloy containing titanium, which have good heat resistance. Each of the first connection pattern CNP1 and the second connection pattern CNP2 may include aluminum having high electrical conductivity. Each of the first connection pattern CNP1 and the second connection pattern CNP2 may have a three-layer structure laminated with titanium/aluminum/titanium.

The light emitting element LD may include an anode AE (or the first electrode), an emission layer EL, and a cathode CE (or the second electrode). The light emitting element LD may be provided in plurality. The plurality of light emitting elements LD may be disposed on the front surface of the base layer BL.

The anode AE may be disposed on the seventh insulating layer 70. The anode AE may be a transparent electrode, a translucent electrode, or a reflective electrode. The anode AE may include a sequentially stacked layered structure of ITO/Ag/ITO. The positions of the anode AE and cathode CE may be interchanged with each other.

A pixel defining layer PDL may be disposed on the seventh insulating layer 70. The pixel defining layer PDL may cover a portion of the anode AE. For example, the pixel defining layer PDL may have an opening PDL-OP that exposes a portion of the anode AE. The emission area LA may be defined to correspond to the opening PDL-OP.

The pixel defining layer PDL may be an organic layer. The pixel defining layer PDL may have a black color. The pixel defining layer PDL may include a black coloring agent. The block coloring agent may include a black dye and a black pigment. The black coloring agent may include carbon black, a metal such as chromium, or oxides thereof. The pixel defining layer PDL may correspond to a light blocking pattern having light blocking characteristics. The pixel defining layer PDL may have light-absorbing properties.

The emission layer EL may be disposed on the anode AE and the pixel defining layer PDL. The emission layer EL may be disposed in the emission opening PDL-OP.

In an embodiment of the inventive concept, a hole control layer may be disposed between the anode AE and the emission layer EL. The hole control layer may include a hole transport layer and may further include a hole injection layer. An electronic control layer may be disposed between the emission layer EL and the cathode CE. The electronic control layer includes an electron transport layer and may further include an electron injection layer.

The encapsulation layer TFE may cover the cathode CE. The encapsulation layer TFE may include a first encapsulation insulating layer IL1, a second encapsulation insulating layer IL2, and a third encapsulation insulating layer IL3. However, an embodiment is not limited thereto, and the encapsulating layer TFE may further include a plurality of inorganic layers and organic layers.

The first encapsulation insulating layer IL1 may be an inorganic layer. For example, the first encapsulation insulating layer IL1 may include silicon nitride, silicon oxide, or a combination thereof. The first encapsulation insulating layer IL1 may be formed through a chemical vapor deposition process. The first encapsulation insulating layer IL1 may prevent external moisture or oxygen from permeating the light emitting element LD.

The second encapsulation insulating layer IL2 may be disposed on the first encapsulation insulating layer IL1 and may be in contact with the first encapsulation insulating layer IL1. The second encapsulation insulating layer IL2 may provide a flat surface on the first encapsulation insulating layer IL1. The second encapsulation insulating layer IL2 may be an organic layer. The second encapsulation insulating layer IL2 may be formed through a solution process such as spin coating, slit coating, or inkjet process. A curve formed on a top surface of the first encapsulation insulating layer IL1 or particles existing on the first encapsulation insulating layer IL1 may be covered by the second encapsulation insulating layer IL2. Thus, layers on the second encapsulation insulating layer IL2 are not strongly affected by uneven surface conditions of the first encapsulation insulating layer IL1.

The third encapsulation insulating layer IL3 may be disposed on the second encapsulation insulating layer IL2 to cover the second encapsulation insulating layer IL2. The third encapsulation insulating layer IL3 may be stably disposed on a relatively flat surface compared to that disposed on the first encapsulation insulating layer IL1. The third encapsulation insulating layer IL3 may encapsulate moisture, etc. released from the second encapsulation insulating layer IL2 to prevent the moisture, etc., from being discharged to the outside. The third encapsulation insulating layer IL3 may be an inorganic layer. The third encapsulation insulating layer IL3 may include silicon oxide (SiOx) or silicon oxynitride (SiON). The third encapsulation insulating layer IL3 may be formed through a chemical vapor deposition process.

The third encapsulation insulating layer IL3 may be optically transparent. For example, the third encapsulation insulating layer IL3 may have visible light transmittance of about 90% or more. The third encapsulation insulating layer IL3 may have relatively high light transmittance compared to that of the first encapsulation insulating layer IL1. Each of the first encapsulation insulating layer IL1, the second encapsulation insulating layer IL2, and the third encapsulation insulating layer IL3 may include a plurality of layers, but this is not a limitation of the disclosure.

The input sensing layer ISL may include at least one conductive layer (or at least one sensor conductive layer) and at least one insulating layer (or at least one sensor insulating layer). In this embodiment, the input sensing layer ISL may include a first insulating layer IS-IL1, a first conductive layer ICL1, a second insulating layer IS-IL2, a second conductive layer ICL2, and a third insulating layer IS-IL3.

The first insulating layer IS-IL1 may be disposed directly on the display panel DP. The first insulating layer IS-IL1 may be an inorganic layer including at least one of silicon nitride, silicon oxynitride, or silicon oxide.

Each of the first conductive layer ICL1 and the second conductive layer ICL2 may have a single-layer structure or a multilayer structure laminated along the third direction DR3. Each of the first conductive layer ICL1 and the second conductive layer ICL2 may include a conductive line defining a mesh-shaped electrode. The conductive line of the first conductive layer ICL1 and the conductive line of the second conductive layer ICL2 may be or may not be connected through a contact hole passing through the second insulating layer IS-IL2. Depending on the type of sensors provided as the input sensing layer ISL, a connection relationship between the conductive lines of the first conductive layer ICL1 and the conductive lines of the second conductive layer ICL2 may be determined.

Each of the first conductive layer ICL1 and the second conductive layer ICL2 each of which has the single-layer structure may include a metal layer or a transparent conductive layer. The metal layer may include molybdenum, silver, titanium, copper, aluminum, or an alloy thereof. The transparent conductive layer may include a transparent conductive oxide such as indium-tin oxide (ITO), indium-zinc oxide (IZO), zinc oxide (ZnOx), or indium zinc tin oxide (IZTO). In addition, the transparent conductive layer may include a conductive polymer such as PEDOT, a metal nanowire, graphene, etc.

Each of the first conductive layer ICL1 and the second conductive layer ICL2 has a multilayer structure that may include a metal layer. The metal layers may have a 3-layer structure of titanium/aluminum/titanium. The multi-layered conductive layer may include at least one metal layer and at least one transparent conductive layer.

The second insulating layer IS-IL2 may be disposed between the first conductive layer ICL1 and the second conductive layer ICL2. The third insulating layer IS-IL3 may cover the second conductive layer ICL2. In an embodiment of the inventive concept, the third insulating layer IS-IL3 may be omitted. Each of the second insulating layer IS-IL2 and the third insulating layer IS-IL3 may include an inorganic layer or an organic layer.

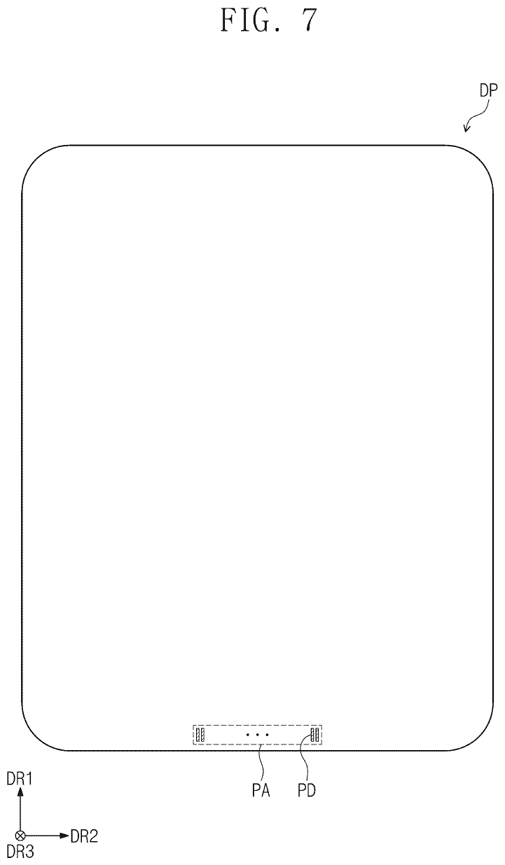

FIG. 7 is a plan view illustrating the rear surface of the display panel according to an embodiment of the inventive concept.

Referring to FIG. 7, the pad electrode PD may be disposed on the rear surface of the display panel DP. Specifically, the pad electrode PD may be disposed on the pad area PA. The pad electrode PD may be provided in plurality. The plurality of pad electrodes PD may be arranged to be spaced apart from each other along the second direction DR2. The pad electrodes PD may electrically connect the signal lines SGL (see FIG. 5) to the main circuit board, respectively.

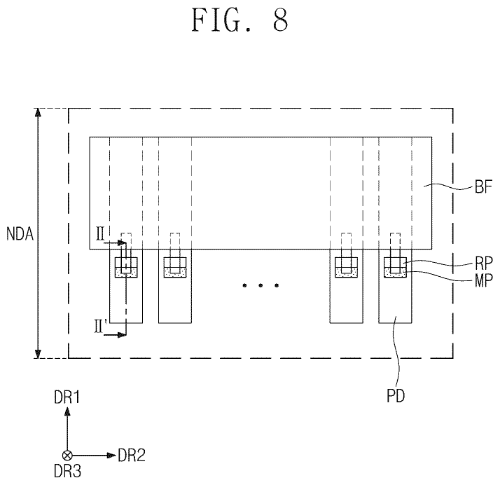

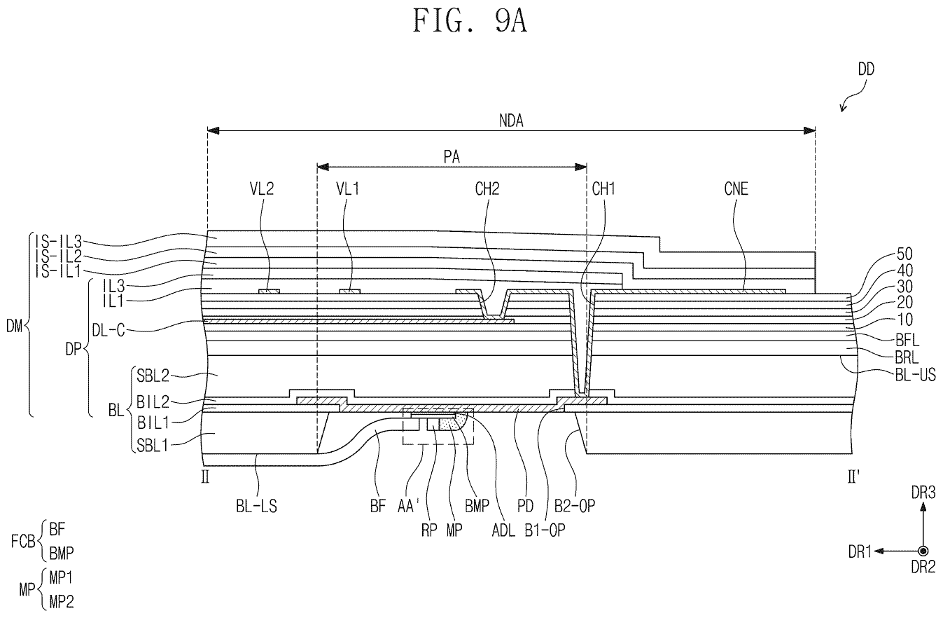

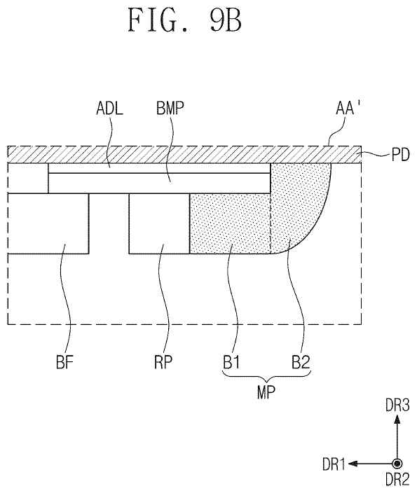

FIG. 8 is a partially enlarged plan view of the display device according to an embodiment of the inventive concept. FIG. 9A is a cross-sectional view of the display device, which is taken along line II-II′ of FIG. 8. FIG. 9B is an enlarged view of an area AA′ of FIG. 9A. FIGS. 8 and 9a are views illustrating a state in which the circuit board is attached to the display panel. Hereinafter, in descriptions with reference to FIGS. 8 to 9B, the same/similar reference numerals may be used for components that are the same/similar to those described in FIGS. 1 to 7, and redundant descriptions thereof may be omitted.

Referring to FIG. 8 and FIG. 9A, the display device DD according to an embodiment of the inventive concept may include a connection electrode CNE and a plurality of pad electrodes PD. The connection electrode CNE may be disposed on the same layer as the first connection pattern CNP1 (see FIG. 6). A portion of the data connection line DL-C overlapping the non-display area NDA may be disposed on the same layer as the first gate GT1 (see FIG. 6) of the silicon transistor S-TFT (see FIG. 6). The data connection line DL-C may be electrically connected to the data line DL (see FIG. 5). However, this embodiment is only an example, and the data connection line DL-C may be disposed on a different layer from the first gate GT1 or may be omitted. If the data connection line DL-C is omitted, a portion of the data line DL may extend and then be connected to the connection electrode CNE. The laminated structure of the display panel DP (see FIG. 4) according to an embodiment of the inventive concept may be changed in various manners as long as the data line DL and the pad electrode PD are connected to each other, but is not limited to any one embodiment.

The pad electrodes PD may be exposed to the outside through a bottom surface BL-LS of the base layer BL for rear-bonding with the circuit board FCB. However, this embodiment is not limited thereto, and the pad electrodes PD may be exposed to the outside through the contact hole, etc., rather than being directly exposed to the outside. The bottom surface BL-LS of the base layer BL may face a top surface BL-US of the base layer BL in the third direction DR3.

The base layer BL may include a first sub-base layer SBL1, a first base insulating layer BIL1, a second base insulating layer BIL2, and a second sub-base layer SBL2. The first base insulating layer BIL1 may be disposed on the first sub-base layer SBL1. The second base insulating layer BIL2 may be disposed on the first base insulating layer BIL1 and may cover the pad electrodes PD. The second sub-base layer SBL2 may be disposed on the second base insulating layer BIL2.

The first sub-base layer SBL1 may be disposed below the first base insulating layer BIL1. The first sub-base layer SBL1 may provide the bottom surface BL-LS of the base layer BL. Each of the first sub-base layer SBL1 and the second sub-base layer SBL2 may include a synthetic resin material, for example, polyimide.

Each of the first base insulating layer BIL1 and the second base insulating layer BIL2 may include an inorganic material. For example, each of the first base insulating layer BIL1 and the second base insulating layer BIL2 may include silicon nitride, silicon oxynitride, or silicon oxide.

A first opening B1-OP may be defined in the first base insulating layer BIL1 and disposed on the first sub-base layer SBL1 to expose a portion of the pad electrodes PD. A second opening B2-OP may be defined in the first sub-base layer SBL1 to expose the pad electrodes PD to the outside of the display module DM. The second opening B2-OP may expose a portion of the first base insulating layer BIL1 to the outside. A size of the second opening B2-OP may be greater than a size of the first opening B1-OP.

The pad electrodes PD may be embedded in the base layer BL. However, this embodiment is not limited thereto, and the pad electrodes PD may also be disposed on the bottom surface BL-LS of the base layer BL. The base layer BL may include a single-layer synthetic resin or may include a plurality of layers, but the first opening B1-OP and the second opening B2-OP may not be defined in some of the layers. The pad electrodes PD disposed on a rear surface of the second insulating layer BIL2 of the base layer BL may be connected to the conductive pattern (not shown) disposed on the top surface BL-US of the base layer BL through the contact hole passing through the base layer BL.

The connection electrode CNE may be connected to the pad electrodes PD through a first contact hole CH1 and connected to the data connection line DL-C through a second contact hole CH2. The first contact hole CH1 and the second contact hole CH2 may be defined in the non-display area NDA. The first contact hole CH1 may be defined to pass through portions of the plurality of insulating layers 10, 20, 30, 40, and 50, the barrier layer BRL, the buffer layer BFL, and the base layer BL. The first contact hole CH1 may be connected to the pad electrodes PD by passing through the second base insulating layer BIL2 of the base layer BL and the second sub-base layer SBL2. The second contact hole CH2 may be defined by passing from the second insulating layer 20 to the fifth insulating layer 50. The connection electrode CNE may be connected to the data line DL (see FIG. 5) through the second contact hole CH2.

The pad electrodes PD may extend in the first direction DR1 and be arranged in the second direction DR2. However, this embodiment is not limited thereto. A shape and arrangement of the pad electrodes PD are not limited to those illustrated in FIG. 8.

The circuit board FCB may be attached to the rear surface of the display panel DP. An adhesive layer may be disposed between the circuit board FCB and the bottom surface BL-LS of the base layer BL. The circuit board FCB may be fixed to the bottom surface BL-LS of the base layer BL by the adhesive layer.

The circuit board FCB may be disposed on the rear surface of the base layer BL. The circuit board FCB may include a base film BF (or film), and a plurality of bump electrodes BMP disposed on the base film BF.

The base film BF may be provided integrally and also electrically connected to the plurality of bump electrodes BMP (shown in FIG. 9A and FIG. 9B). Here, a plurality of lines may be disposed inside of the base film BF. However, this embodiment is not limited thereto, and the base film BF may be attached only to the plurality of bump electrodes BMP, but may not be electrically connected. In this case, the base film BF may include a synthetic resin material, for example, polyimide.

Each of the bump electrodes BMP may be disposed on a surface facing the rear surface of the base layer BL on the base films BF. Each of the bump electrodes BMP may protrude from a side edge of the base film BF.

The bump electrodes BMP may be electrically connected to the pad electrodes PD. The bump electrodes BMP may be disposed corresponding to the pad electrodes PD. That is, one bump electrode BMP may correspond to one pad electrode PD. The bump electrodes BMP may extend in the first direction DR1 and be arranged in the second direction DR2. A planar area of each of the pad electrodes PD may be greater than a planar area of each of the bump electrodes BMP. Thus, an allowable alignment tolerance range during the bonding of the pad electrodes PD and the bump electrodes BMP may increase to prevent misalignment from occurring. However, this embodiment is only an example, and if the pad electrodes PD and the bump electrodes BMP may be connected to each other, the surface area of each of the pad electrodes PD and the bump electrodes BMP may be variously changed, but is not limited to any one embodiment.

The display device DD (see FIG. 2) according to an embodiment of the inventive concept may further include metal patterns MP that electrically connect the bump electrodes BMP to the pad electrodes PD, and insulating patterns RP. The metal patterns MP may be provided in number corresponding to each of the number of pad electrodes PD and the number of bump electrodes BMP. The metal patterns MP may be disposed within the second opening B2-OP. The metal patterns MP may cover the entire side surfaces of the bump electrodes BMP.

Each of the metal patterns MP may be a pattern of hardened metal ink. The metal patterns MP may include solder paste. The metal patterns MP may be provided from metal ink including silver (Ag) or copper (Cu). The metal patterns MP may be disposed on each pad electrode PD exposed by the second opening B2-OP. The metal patterns MP may be provided by hardening and then patterning the metal ink. The metal patterns MP may be formed at a low temperature and electrically connect the pad electrodes PD to the bump electrodes BMP and simultaneously bond the pad electrodes PD to the bump electrodes BMP without a high-temperature pressurizing process. The process of forming the metal patterns MP will be described in detail later.

The insulating pattern RP may be provided in plurality. The insulating patterns RP may be respectively disposed between the side edge (hereinafter, referred to as a side edge of the base film) extending along the second direction DR2 of the base film BF and the metal patterns MP. The insulating patterns RP may be disposed to be spaced apart from the base film BF. The insulating patterns RP may overlap the bump electrodes BMP on the plane. The insulating patterns RP are spaced apart from each other and may be in contact with the metal patterns MP, respectively. The insulating patterns RP may be in contact with the side surfaces of the metal patterns MP. A surface of each of the insulating patterns RP may be flush with a surface of each of the metal patterns MP.

Each of the insulating patterns RP may be a UV curable resin. That is, the insulating pattern RP may be a resin that is hardened by ultraviolet (UV) rays. For example, each of the insulating patterns RP may include at least one of polyacrylic acid, polymethyl methacrylate, polyacrylamide, or polybutyl acrylate. Each of the insulating patterns RP may be a transparent resin. Thus, a boundary between the insulating patterns RP and the metal patterns MP may be visually confirmed.

Referring to FIGS. 9A and 9B, an adhesive layer ADL may be further disposed between the pad electrodes PD and the bump electrodes BMP, and between the base film BF and the base layer BL. In an embodiment, the adhesive layer ADL may be a non-conductive film NCF. In this case, electrical connection between the pad electrodes PD and the bump electrodes BMP may be performed only through the metal patterns MP.

According to an embodiment of the inventive concept, each of the metal patterns MP may include a first portion B1 and a second portion B2. The first portion B1 may overlap at least a portion of the bump electrodes BMP on the plane, and the second portion B2 may not overlap the bump electrodes BMP on the plane. The second portion B2 may cover the side surfaces of the bump electrodes BMP. The second portion B2 may be electrically connected to the pad electrodes PD and contact the pad electrodes PD.

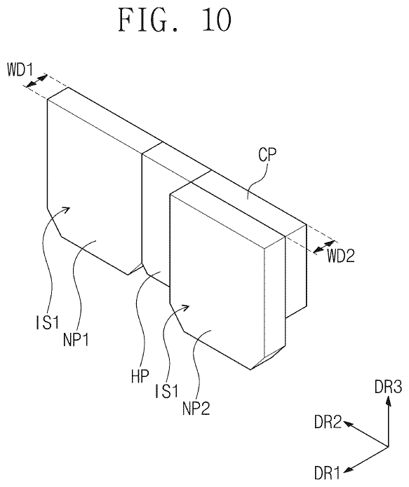

FIG. 10 is a perspective view illustrating an apparatus for manufacturing the display device according to an embodiment of the inventive concept.

Referring to FIG. 10, the apparatus for manufacturing the display device EM may include a first nozzle part NP1, a hardening part HP, a connection jig CP, and a second nozzle part NP2.

The first nozzle part NP1 may supply a resin onto the bump electrodes BMP. The hardening part HP may be connected to the first nozzle part NP1. The hardening part HP may harden the resin by irradiating the resin with ultraviolet rays. The connection jig CP may be connected to the hardening part HP.

The second nozzle part NP2 may be connected to the connection jig CP. The first nozzle part NP1 and the second nozzle part NP2 may be disposed across the hardening part HP from each other, with the second nozzle part NP2 but not the first nozzle part NP1 being on the connection jig CP. The second nozzle part NP2 may supply ink onto the bump electrodes BMP. Here, the ink may contain at least one of silver (Ag), copper (Cu), or aluminum (Al).

Referring to FIG. 10, a second surface IS2 of the second nozzle part NP2 may protrude in the first direction DR1 with respect to a first surface IS1 of the first nozzle part NP1. In FIG. 10, widths of the first nozzle part NP1, the hardening part HP, and the connection jig CP in the first direction DR1 are illustrated to be the same, but this is not limited thereto. For example, a width WD2 (hereinafter, referred to as a second width) of the connection jig CP in the first direction DR1 may be greater than a width WD1 (hereinafter, referred to as a first width) of the first nozzle part NP1 in the first direction DR1. A degree to which the second surface IS2 protrudes in the first direction DR1 with respect to the plane of the first surface IS1 may be controlled to adjust an amount of resin and ink supplied from each of the first nozzle part NP1 and the second nozzle part NP2.

In this embodiment, the process of supplying the resin onto the bump electrodes BMP using the first nozzle part NP1, the process of hardening the resin using the hardening part HP, and the process of supplying the ink onto the bump electrodes BMP using the second nozzle part NP2 may be performed sequentially through the apparatus for manufacturing the display device DD.

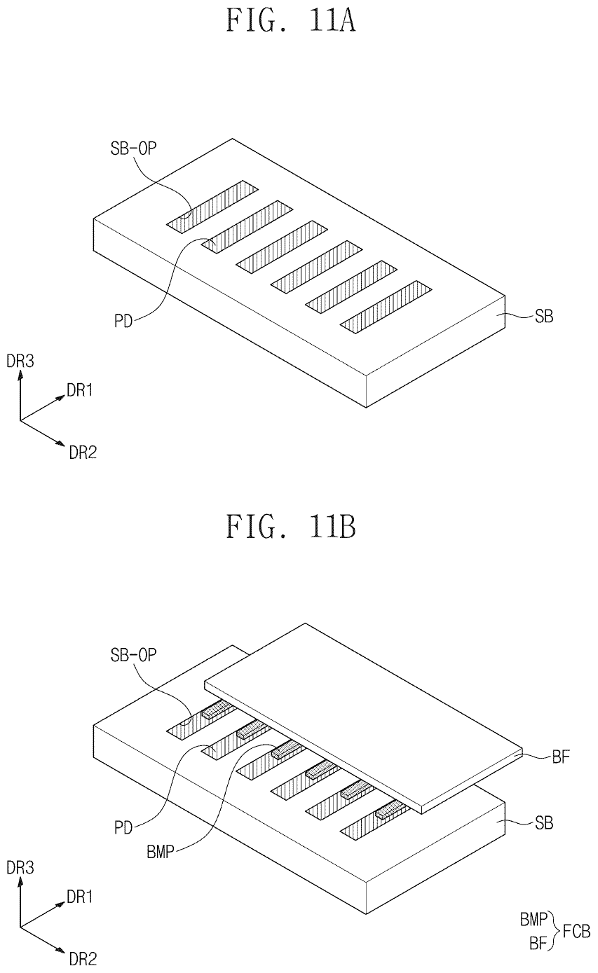

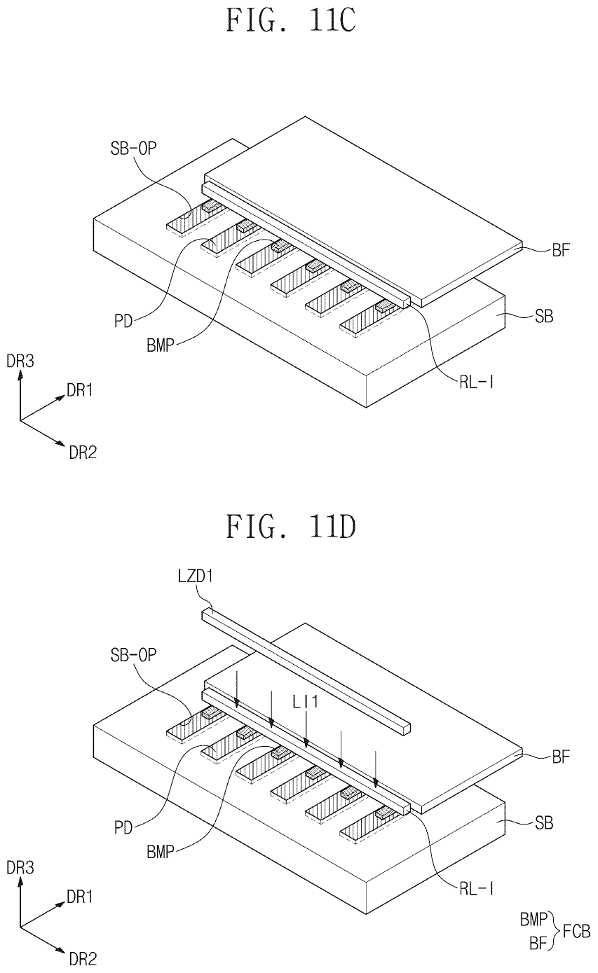

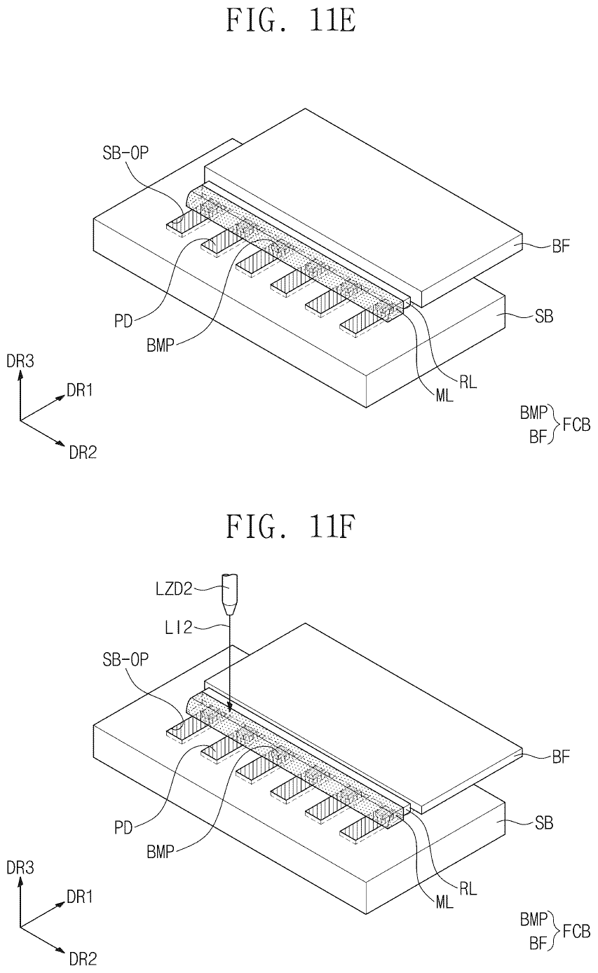

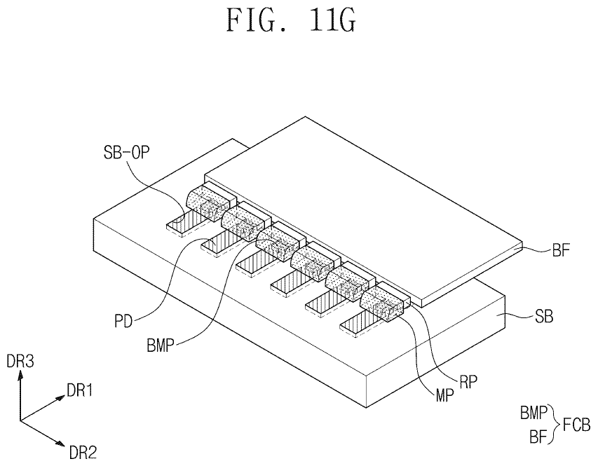

FIGS. 11A to 11G are views illustrating a method for manufacturing a display device according to an embodiment of the inventive concept. Hereinafter, in descriptions with reference to FIGS. 11A to 11G, the same/similar reference numerals are used for configurations similar to those described in FIGS. 1 to 9B, and redundant descriptions will be omitted.

Referring to FIG. 11A, an opening SB-OP in a substrate SB may be formed to expose a plurality of pad electrodes PD. The substrate SB and the pad electrodes PD illustrated in FIG. 11A may correspond to the base layer BL and the pad electrodes PD illustrated in FIG. 9A. The pad electrodes PD may be exposed to the outside through a second opening B2-OP as illustrated in FIG. 9A.

Referring to FIG. 11B, a circuit board FCB is provided on the substrate SB. The circuit board FCB illustrated in FIG. 11B may correspond to the circuit board FCB illustrated in FIG. 9A. The circuit board FCB may include a base film BF and a plurality of bump electrodes BMP disposed on the base film BF. The plurality of bump electrodes BMP may be provided to overlap the plurality of pad electrodes PD on the plane, respectively. The bump electrodes BMP may be in contact with the pad electrodes PD, respectively.

Referring to FIG. 11C, a preliminary resin layer RL-I may be formed on the plurality of bump electrodes BMP. The preliminary resin layer RL-I may be formed to be spaced apart from the base film BF of the circuit board FCB. The preliminary resin layer RL-I may be formed to be in contact with a top surface of each of the plurality of bump electrodes BMP. The preliminary resin layer RL-I may be formed by the resin supplied through the first nozzle part NP1 of the apparatus for manufacturing the display device DD, which is illustrated in FIG. 10.

Referring to FIG. 11D, the resin layer RL is formed by hardening the preliminary resin layer RL-I. The hardening of the preliminary resin layer may be performed before the patterning the resin layer and the metal layer, which will be described later. The hardening the preliminary resin layer RL-I may be performed by irradiation with UV rays (or photocuring). That is, the hardening the preliminary resin layer RL-I may include irradiating the preliminary resin layer RL-I with light LI1. Specifically, a UV irradiation device LZD1 may be disposed above the resin layer RL to irradiate UV rays, thereby hardening the resin layer RL. However, an embodiment is not limited thereto, and the hardening of the preliminary resin layer RL-I may be omitted.

A wavelength range of the light LI1 may be at least 350 nm and no more than about 450 nm. The light LI1 may be provided across the entire surface of the preliminary resin layer RL-I. The resin layer RL may be formed by the UV hardening through the hardening part HP of the apparatus for manufacturing the display device DD, which is illustrated in FIG. 10.

Referring to FIG. 11E, a metal layer ML is formed on the plurality of bump electrodes BMP. The metal layer ML may be formed so that the resin layer RL is disposed between the metal layer ML and the base film BF. The metal layer ML may be formed to be in contact with the resin layer RL. The metal layer ML may be formed to completely cover side surfaces of the bump electrodes BMP. The metal layer ML may be formed to be further spaced apart from the base film BF of the circuit board FCB in the first direction DR1 than the resin layer RL. The metal layer ML may include at least one of silver (Ag), copper (Cu), or aluminum (Al). The metal layer ML may be formed by hardening metal ink. The metal layer ML may be provided as a liquid by the ink supplied through the second nozzle part NP2 of the apparatus for manufacturing the display device DD, which is illustrated in FIG. 10.

It is possible to reduce or prevent the metal ink from permeating into the base film BF of the circuit board FCB during the forming of the metal layer ML. Spreading of the metal ink may be controlled to prevent cracks in an upper portion of the metal ink, which may occur when the metal ink seeps into the space between the bump electrodes BMP and the pad electrodes PD. In addition, compared to the case in which the resin layer RL is not formed, a phenomenon of lack of the metal ink below the bump electrodes BMP may be prevented or reduced. Thus, an area on which the metal patterns MP are in contact with the pad electrodes PD may increase to reduce resistance that may occur between the pad electrodes PD and the bump electrodes BMP. As a result, an electrically reliable display device DD (see FIG. 2) may be provided.

Referring to FIG. 11F and FIG. 11G, the resin layer RL and the metal layer ML may be patterned. Specifically, a laser irradiation device LZD2 may be disposed above the resin layer RL and the metal layer ML to irradiate laser LI2, thereby patterning the resin layer RL and the metal layer ML.

The metal layer ML may be patterned by the laser LI2 to form a plurality of metal patterns MP that are separated from each other, and the resin layer RL may be patterned by the laser LI2 to form a plurality of insulating patterns RP that are separated from each other. The metal patterns MP and the insulating patterns RP may correspond to the metal patterns MP and the insulating patterns RP illustrated in FIG. 9A, respectively. The metal patterns MP and the insulating patterns RP may electrically connect the pad electrodes PD to the bump electrodes BMP. The number of metal patterns MP and the number of insulating patterns RP may be the same as the number of pad electrodes PD and the number of bump electrodes BMP, respectively. The metal patterns RP may be formed by hardening the metal ink containing silver (Ag) or copper (Cu).

In an embodiment, the metal layer ML may be hardened after the resin layer RL and the metal layer ML are patterned. The metal layer ML may be hardened through the photocuring as illustrated in FIG. 11D. That is, hardening the metal layer ML may be achieved by irradiating the light LI1 (see FIG. 11D) onto the metal layer ML. However, the inventive concept is not limited thereto, and the hardening the metal layer ML may be performed before irradiating the laser LI2 described in FIG. 11F.

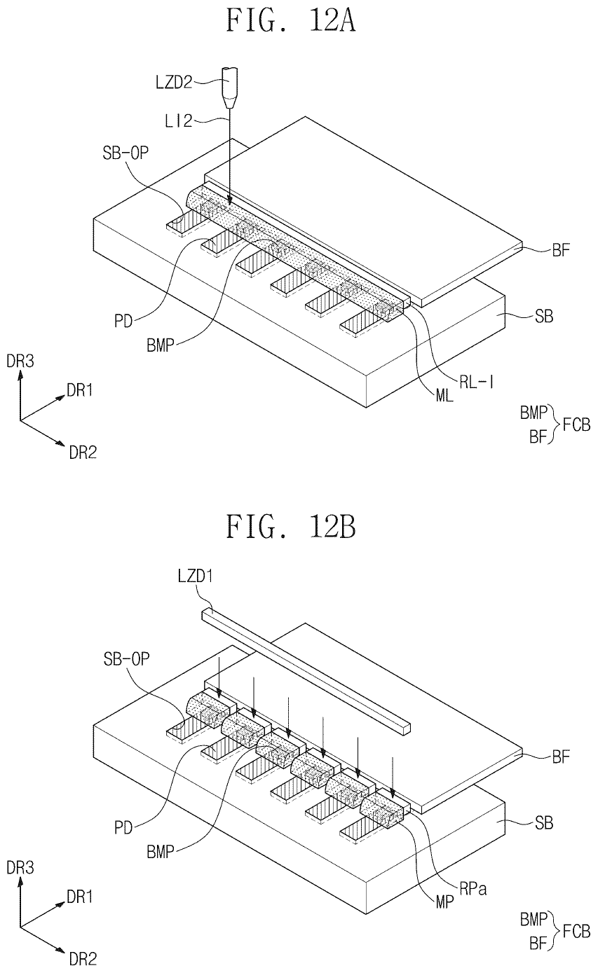

FIGS. 12A and 12B are views illustrating the method of manufacturing a display device according to an embodiment of the inventive concept. Hereinafter, in the description with reference to FIGS. 12A and 12B, the same reference numerals are used for configurations that are similar to those described in FIGS. 1 to 11G, and redundant descriptions will be omitted.

Referring to FIGS. 12A and 12B, insulating patterns RPa and the metal patterns MP may be hardened after the patterning of the preliminary resin layer RL-I and the metal layer ML. The hardening of the insulating patterns RPa and the hardening of the metal patterns MP may be performed simultaneously. The insulating patterns RPa may be hardened by exposure to intense pulsed light (IPL).

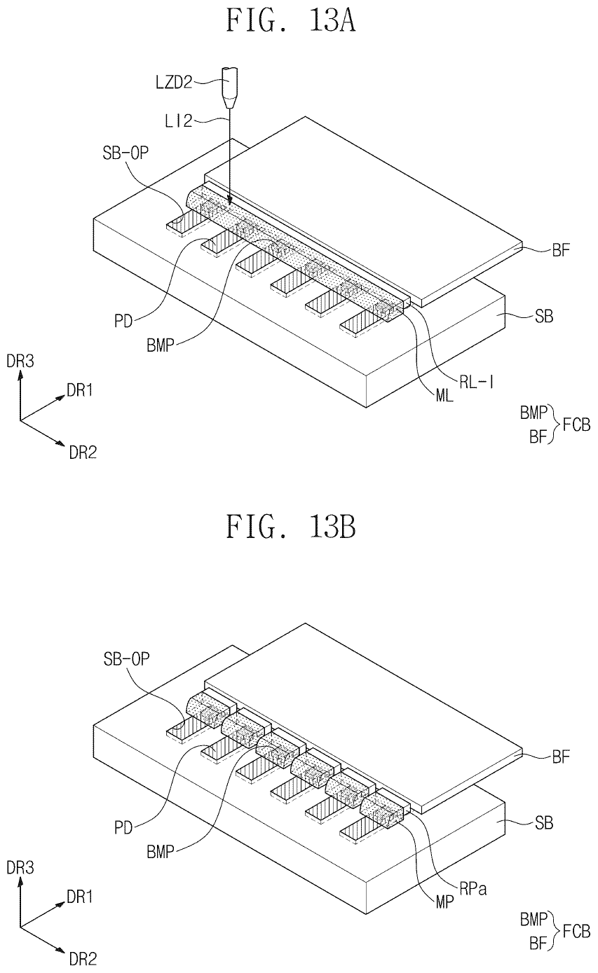

FIGS. 13A and 13B are views illustrating the method for manufacturing the display device according to an embodiment of the inventive concept. Hereinafter, in the description with reference to FIGS. 13A and 13B, the same reference numerals are used for configurations that are similar to those described in FIGS. 1 to 12B, and redundant descriptions will be omitted.

Referring to FIGS. 13A and 13B, the hardening of the preliminary resin layer RL-I following the forming of the preliminary resin layer RL-I may be omitted. Unlike what is illustrated in FIGS. 12A and 12B, in an embodiment of the inventive concept, after forming the insulating patterns RPa and the metal patterns MP by patterning the preliminary resin layer RP-I and the metal layer ML, the insulating patterns RPa and the metal patterns MP do not have to be hardened.

In the display device according to the embodiment of the inventive concept, the resin layer may be formed before the metal layer is formed. During the process of hardening the metal ink to form the metal layer, as the resin layer is formed, the metal link may be reduced or prevented from permeating into the film of the circuit board. The spreading of the metal ink may be controlled to prevent the cracks from forming. The cracks may be caused by the metal ink seeping into the space between the bump electrodes and the pad electrodes and hardening.

It will be apparent to those skilled in the art that various modifications and variations can be made in the inventive concept. Thus, it is intended that the present disclosure covers the modifications and variations of this invention provided they come within the scope of the appended claims and their equivalents. Hence, the protective scope of the inventive concept shall be determined by the technical scope of the accompanying claims.

1. A method of installing stationary structural members of a solar panel racking structure, the method comprising:
positioning a jig on a surface relative to a datum on the surface;
using the jig as a guide and driving a first plurality of stationary structural members into the ground at fixed positions relative to one another;
removing the jig from the first plurality of stationary structural members;
repositioning the jig to a desired position relative to the datum; and
repeating the steps of using the jig as a guide, driving a second plurality of stationary members into the ground and removing the jig,
where the using the jig as a guide and driving comprises driving each of the first plurality of stationary members into the ground through an associated one of a plurality of guides located on the jig,
where the step of removing comprises lifting the jig so each of the plurality of guides no longer surrounds its associated one of the first plurality of stationary structural members, where the jig is rectangular and the guides are mounted to exterior corners of the rectangular jig, and the step of using the jig as a guide and driving a first plurality of stationary structural members into the ground comprises driving a first and a second stationary structural member of the first plurality of stationary structural members into the ground such that a top surface of each of the first and the second stationary structural members is a height H1 above the ground, and driving a third and a fourth stationary structural member of the first plurality of stationary structural members into the ground such that a top surface of each of the third and the fourth stationary structural members is a height H2 above the ground, where height H1 is not equal to height H2.

2. The method of claim 9, where the using the jig as a guide and driving comprises driving each of the first plurality of stationary members into the ground through an associated one of a plurality of guides located on the jig.

3. The method of claim 1, where the using the jig as a guide and driving comprises driving each of the first plurality of stationary members into the ground through an associated one of a plurality of eyelets located on the jig.

4. The method of claim 1, where the using the jig as a guide and driving comprises driving each of the first plurality of stationary members into the ground through an associated one of a plurality of tubing segments located on the jig.

5. The method of claim 2, where the step of removing comprises lifting the jig so each of the plurality of guides no longer surrounds its associated one of the first plurality of stationary structural members.

6. (canceled)

7. (canceled)

8. (canceled)

9. A method of installing stationary structural members of a solar panel racking structure, the method comprising:
positioning a jig on a surface relative to a datum on the surface;
using the jig as a guide and driving a first plurality of stationary structural members into the ground at fixed positions relative to one another;
removing the jig from the first plurality of stationary structural members;
repositioning the jig to a desired position relative to the datum; and
repeating the steps of using the jig as a guide, driving a second plurality of stationary members into the ground and removing the jig,
where the jig is rectangular and the guides are mounted to exterior corners of the rectangular jig, and the step of using the jig as a guide and driving a first plurality of stationary structural members into the ground comprises driving a first and a second stationary structural member of the first plurality of stationary structural members into the ground such that a top surface of each of the first and the second stationary structural members is a height H1 above the ground, and driving a third and a fourth stationary structural member of the first plurality of stationary structural members into the ground such that a top surface of each of the third and the fourth stationary structural members is a height H2 above the ground, where height H1 is not equal to height H2.

10. The method of claim 9, where the using the jig as a guide and driving comprises driving each of the first plurality of stationary members into the ground through an associated one of a plurality of eyelets located on the jig.

11. The method of claim 9, where the using the jig as a guide and driving comprises driving each of the first plurality of stationary members into the ground through an associated one of a plurality of tubing segments located on the jig.
